(19) United States
(12) Patent Application Publication
(10) Pub. No.: US 2023/0400761 A1
(43) Pub. Date: Dec. 14, 2023

(54) IMPRINT APPARATUS, IMPRINT METHOD AND ARTICLE MANUFACTURING METHOD

(71) Applicant: CANON KABUSHIKI KAISHA, Tokyo (JP)

(72) Inventor: TOSHIHIKO NISHIDA, Tochigi (JP)

(21) Appl. No.: 18/318,801

(22) Filed: May 17, 2023

(30) Foreign Application Priority Data
Jun. 9, 2022 (JP) 2022-093817

(51) Int. Cl. G03F 7/00; G03F 7/20

(52) U.S. Cl. CPC G03F 7/0002; G03F 7/70825; G03F 7/7095; G03F 7/2002

(57) ABSTRACT

An imprint apparatus including a substrate holding unit including a plurality of holding regions whose pressures to a substrate are independently controlled, and configured to hold the substrate on the plurality of holding regions, a first obtaining unit configured to obtain first information about a pressing force applied to a mold when the mold and an imprint material on the substrate are brought into contact with each other, and a control unit configured to control, based on the first information obtained by the first obtaining unit, the pressure between the substrate and each of the plurality of holding regions in a state in which the mold and the imprint material on the substrate are in contact with each other such that deformation that occurs in the substrate due to the pressing force falls within an allowable range.

### BACKGROUND OF THE INVENTION

### Field of the Invention

The present invention relates to an imprint apparatus, an imprint method and an article manufacturing method.

### Description of the Related Art

As a lithography technique for manufacturing a semiconductor device or the like, there is known an imprint technique for molding an imprint material (curable composition) on a substrate using a mold. In an imprint apparatus using the imprint technique, an imprint material is cured in a state in which a mold and the imprint material on a substrate are in contact, and the mold is released from the cured imprint material, thereby forming a pattern of the imprint material on the substrate.

The imprint apparatus is required to accurately transfer the pattern of the mold to the substrate. For this purpose, Japanese Patent Laid-Open No. 2020-92178 proposes a technique for accurately overlaying (aligning) (a pattern region with a pattern of) a mold and (a transfer region (shot region) of) a substrate. Japanese Patent Laid-Open No. 2020-92178 discloses a technique for controlling the pressure of a substrate holding unit configured to hold the substrate based on the shape information of the substrate or overlay information.

In the conventional technique, however, when adjusting the overlay of the mold and the substrate, if the force (pressing force) for pressing the mold is changed, the mold or the substrate is deformed due to the change, and it may be impossible to set the overlay accuracy to an intended accuracy.

### SUMMARY OF THE INVENTION

The present invention provides a technique advantageous in terms of an overlay accuracy between a mold and a substrate.

According to one aspect of the present invention, there is provided an imprint apparatus that forms a pattern of an imprint material on a substrate using a mold, including a substrate holding unit including a plurality of holding regions whose pressures to the substrate are independently controlled, and configured to hold the substrate on the plurality of holding regions, a first obtaining unit configured to obtain first information about a pressing force applied to the mold when the mold and the imprint material on the substrate are brought into contact with each other, and a control unit configured to control, based on the first information obtained by the first obtaining unit, the pressure between the substrate and each of the plurality of holding regions in a state in which the mold and the imprint material on the substrate are in contact with each other such that deformation that occurs in the substrate due to the pressing force falls within an allowable range.

Further aspects of the present invention will become apparent from the following description of exemplary embodiments with reference to the attached drawings.

### BRIEF DESCRIPTION OF THE DRAWINGS

FIG. 1 is a schematic view illustrating configurations of an imprint apparatus according to an aspect of the present invention.

FIGS. 2A to 2E are views for describing a substrate and the configuration of a substrate holding unit.

FIGS. 3A to 3C are views schematically illustrating the shapes of a mold and the substrate in an imprint process.

FIG. 4 is a flowchart for describing the operation of the imprint apparatus.

FIGS. 5A and 5B are views illustrating the substrate holding unit viewed from an upper surface.

FIG. 6 is a view for describing the position deviation of the substrate held by the substrate holding unit.

FIGS. 7A to 7F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

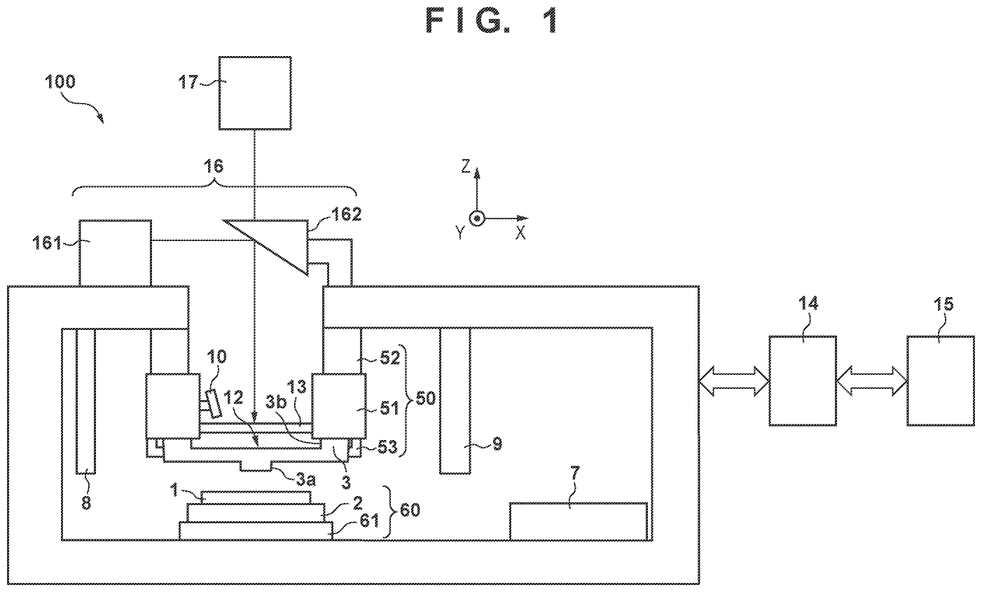

FIG. 1 is a schematic view illustrating configurations of an imprint apparatus 100 according to an aspect of the present invention. The imprint apparatus 100 is a lithography apparatus employed in a lithography step that is a manufacturing step for a device such as a semiconductor element, a liquid crystal display element, or magnetic storage medium as an article to form a pattern on a substrate. The imprint apparatus 100 performs an imprint process for forming a pattern of an imprint material on a substrate using a mold. More specifically, the imprint apparatus 100 brings an uncured imprint material supplied (arranged) on the substrate into contact with the mold, and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive.

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are ex, e, and OZ, respectively.

As an imprint material curing method, in this embodiment, the imprint apparatus 100 employs a photocuring method for curing an imprint material by irradiating it with light. However, the present invention is not limited to this. For example, as the imprint material curing method, the imprint apparatus 100 can also employ a heat-curing method for curing an imprint material by applying heat.

As shown in FIG. 1, the imprint apparatus 100 includes a prealignment unit 7, a dispenser 8, an off-axis alignment measurement system 9, and an alignment measurement system 10. Also, the imprint apparatus 100 includes a light transmitting member 13, a control unit 14, a console unit 15, an irradiation unit 16, a filling monitor 17, a mold stage 50, and a substrate stage 60.

The irradiation unit 16 irradiates an imprint material on a substrate with light (for example, UV rays) via a mold 3. The irradiation unit 16 includes, for example, a light source unit 161 that emits light to cure the imprint material on the substrate, and an optical member 162 configured to guide the light emitted from the light source unit 161 to the imprint material on the substrate. The optical member 162 includes an optical element configured to adjust the light emitted from the light source unit 161 to light appropriate for an imprint process.

The mold 3 has a rectangular outer shape. A three-dimensional pattern 3a is formed on a surface (pattern surface) of the mold 3 facing a substrate 1. The mold 3 is made of a material capable of transmitting the light (UV rays) from the irradiation unit 16, for example, silica glass. The mold 3 includes a cavity (concave portion) 3b configured to facilitate deformation of the pattern 3a. The cavity 3b has a circular planar shape, and its depth (thickness) is appropriately set in accordance with the shape or material of the mold 3.

The light transmitting member 13 is arranged above the cavity 3b. The light transmitting member 13 is a member configured to form, as an enclosed space, a space 12 surrounded by the cavity 3b and a part of an opening region provided in the mold stage 50. By adjusting the pressure in the space 12 via a pressure adjustment device (not shown) connected to the space 12, the pattern 3a of the mold 3 can be deformed, for example, the pattern 3a of the mold 3 can be deformed in a convex shape to the substrate side.

The mold stage 50 includes a mold holding unit 51 that holds the mold 3 by a vacuum suction force or an electrostatic force, a mold driving unit 52 that drives the mold holding unit 51 in the Z direction (vertical direction), and a mold deformation mechanism 53. In each of the mold holding unit 51 and the mold driving unit 52 (mold stage 50), an opening region configured to irradiate an imprint material on a substrate with light from the irradiation unit 16 is provided at the center.

The mold driving unit 52 includes an actuator, for example, a voice coil motor or an air cylinder. To bring the mold 3 into contact with the imprint material on the substrate or release the mold 3 from the imprint material on the substrate, the mold driving unit 52 drives (the mold 3 held by) the mold holding unit 51 in the Z direction. Note that the mold driving unit 52 may have a function of driving the mold holding unit 51 not only in the Z direction but also in the X direction or the Y direction (that is, a function of adjusting the position of the mold 3 in the X direction or the Y direction). Also, the mold driving unit 52 may have a function of adjusting the position of the mold holding unit 51 in the OZ direction or a function of adjusting the tilt of the mold holding unit 51.

The mold deformation mechanism 53 applies an external force or displacement to a side surface of the mold 3 held by the mold holding unit 51, thereby deforming (the pattern 3a of) the mold 3 (correcting the shape of the mold 3). The mold deformation mechanism 53 is configured to include, for example, a plurality of actuators to pressurize a plurality of points on each side surface of the mold 3.

On the substrate 1, a plurality of shot regions are arrayed in a matrix. Here, a shot region means a region (transfer region) to which the pattern 3a of the mold 3 is transferred by one imprint process. In this embodiment, to maximize the effective area of the substrate 1 (the total area of regions where the pattern 3a of the mold 3 is transferred), the imprint process is performed not only for shot regions inside the substrate 1 but also for peripheral shot regions including the outer periphery of the substrate 1. A peripheral shot region is a shot region partially chipped (protruding from the outer periphery of the substrate 1) and is also called a chipped shot region.

The substrate stage 60 includes a substrate holding unit 2 that holds the substrate 1, and a substrate driving unit 61 that drives (the substrate 1 held by) the substrate holding unit 2 in the X direction and the Y direction. The substrate driving unit 61 includes, for example, a linear motor, and may be formed by a plurality of driving systems such as a coarse driving system and a fine driving system. Also, the substrate driving unit 61 may have a function of driving the substrate holding unit 2 not only in the X direction and the Y direction but also in the Z direction (that is, a function of adjusting the position of the substrate 1 in the Z direction). Also, the substrate driving unit 61 may have a function of adjusting the position of the substrate holding unit 2 in the OZ direction or a function of adjusting the tilt of the substrate holding unit 2.

The prealignment unit 7 includes a prealignment stage (not shown) on which the substrate 1 is mounted, and a prealignment sensor (not shown) that measures the position of the substrate 1 mounted on the prealignment stage. The prealignment sensor detects a notch or an orientation flat provided on the substrate 1, thereby measuring the position of the substrate 1. The prealignment stage is driven based on the measurement result of the prealignment sensor, and the substrate 1 mounted on the prealignment stage is transferred to a conveyance hand (not shown) at that position. The conveyance hand arranges the substrate 1 on the substrate holding unit 2. Note that instead of driving the prealignment stage, the position (reception position) of the conveyance hand that receives the substrate 1 from the prealignment stage or the position of the substrate holding unit 2 that receives the substrate 1 from the conveyance hand may be changed based on the measurement result of the prealignment sensor.

In this embodiment, the position of the substrate stage 60 is measured using an encoder system including a scale provided on a housing, and a head (optical device) provided on the substrate driving unit 61. However, the present invention is not limited to this. For example, the position of the substrate stage 60 may be measured using an interferometer system including an interferometer provided on the housing, and a reflecting mirror provided on the substrate driving unit 61.

The off-axis alignment measurement system 9 and the alignment measurement system 10 are used for prealignment measurement for measuring the relative position of the mold 3 and (each shot region of) the substrate 1. The off-axis alignment measurement system 9 and the alignment measurement system 10 individually measure the positions of the substrate 1 and the mold 3, respectively, based on device coordinates as a reference under the control of the control unit 14. The alignment measurement system 10 detects (observes) a mark provided on the mold 3, thereby measuring the position of the mold 3 based on the position reference of the alignment measurement system 10. On the other hand, the off-axis alignment measurement system 9 detects a plurality of marks provided on the substrate 1 held by the substrate holding unit 2, thereby measuring the position of (each shot region of) the substrate 1 based on the position reference of the substrate holding unit 2. Statistic calculation processing (global alignment) for estimating the position coordinates of all shot regions of the substrate 1 is then executed.

Also, the alignment measurement system 10 measures the position deviations between an alignment mark provided on the substrate 1 and an alignment mark provided on the mold 3 (that is, the position deviations between the substrate 1 and the mold 3) in the X direction and the Y direction. Under the control of the control unit 14, the position of the substrate stage 60 is adjusted based on the position deviations measured by the alignment measurement system 10, thereby overlaying (aligning) (the pattern 3a of) the mold 3 and (the shot region of) the substrate 1.

The dispenser 8 has a function of arranging (supplying) an imprint material on the substrate. The dispenser 8, for example, discharges droplets of the imprint material to each shot region on the substrate. The dispenser 8 may individually arrange the imprint material in each of a plurality of shot regions on the substrate or may arrange the imprint material in several shot regions at once.

The filling monitor 17 (spread camera) observes the contact state between the mold 3 and the imprint material arranged (supplied) (in the shot region) on the substrate. When the contact state between the mold 3 and the imprint material on the substrate is observed by the filling monitor 17, a defective portion caused by unfilled particles or imprint material can be specified. The filling monitor 17 includes, for example, light source, an image capturing element, and an optical system. As the light source, for example, an LED that emits light having a wavelength to which the imprint material is not photosensitive is used, and as the image capturing element, a two-dimensional sensor such as a CCD sensor is used. The optical system includes an illumination system that evenly illuminates (the shot region of) the substrate 1 with light from the light source, and an imaging system that makes the substrate 1 and the image capturing element optically conjugate.

The control unit 14 is formed by, for example, a computer including a CPU, a memory, and the like, and comprehensively controls the units of the imprint apparatus 100 in accordance with a program stored in the memory, thereby operating the imprint apparatus 100.

In this embodiment, the control unit 14 controls an imprint process for forming a pattern of the imprint material on the substrate using the mold 3 (transferring the pattern 3a of the mold 3 to the imprint material on the substrate) and processes associated with this. Here, the imprint process typically includes an arrangement step, a contact step, a filling step, a curing step, and a release step. The arrangement step is a step of arranging (supplying) an imprint material onto a substrate. The contact step is a step of bringing the imprint material on the substrate into contact with the mold 3. The filling step is a step of filling the pattern 3a of the mold 3 with the imprint material in a state in which the imprint material on the substrate and the mold 3 are in contact. The curing step is a step of curing the imprint material in a state in which the imprint material on the substrate and the mold 3 are in contact. The release step is a step of releasing the mold 3 from the cured imprint material on the substrate.

The console unit 15 is an interface that includes a computer including an input device such as a keyboard or a mouse, and a display and is configured to share information between the user and the imprint apparatus 100 (control unit 14). The console unit 15 outputs (transmits) information about the imprint process input by the user to the control unit 14. The information about the imprint process, which is input to the console unit 15, is recorded as a log in the imprint apparatus 100 and can be confirmed before and after the imprint process. Here, the information about the imprint process includes an imprint recipe in which various imprint conditions when forming the pattern of the imprint material on the substrate are described. The imprint recipe includes, for example, a force (pressing force) applied to the mold 3 when bringing the mold 3 into contact with the imprint material on the substrate, a shot layout showing the array of shot regions on the substrate, and a drop pattern showing the array of droplets of the imprint material to be arranged on the substrate.

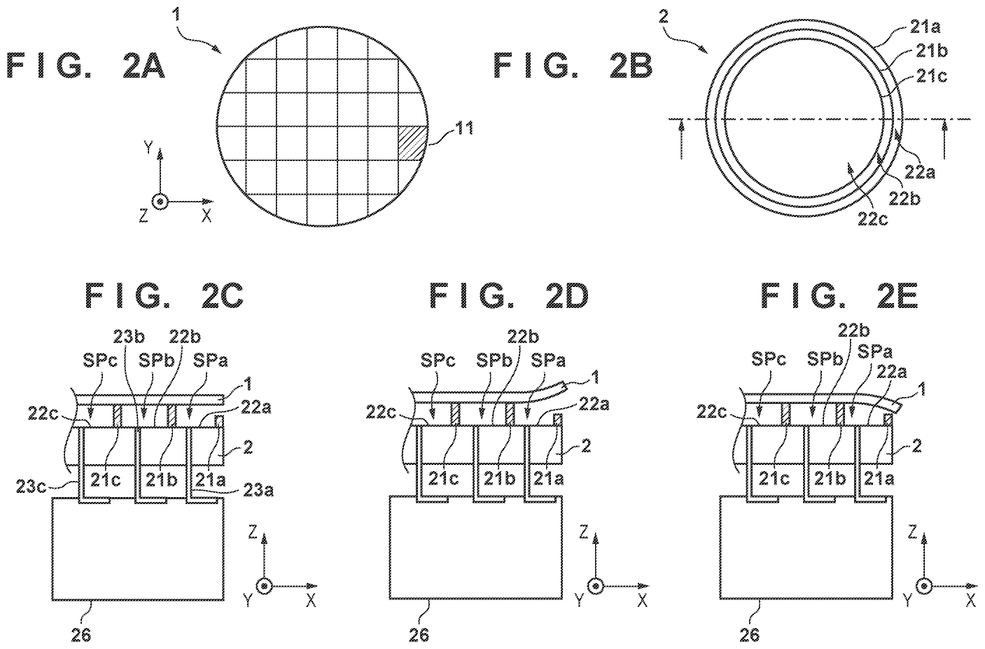

The substrate 1 and the configuration of the substrate holding unit 2 will be described with reference to FIGS. 2A to 2E. FIG. 2A is a view illustrating a shot layout showing the array of shot regions on the substrate. The shot regions are regions defined on the substrate, and the imprint process is performed on each region. Note that in FIG. 2A, a shot region 11 of a plurality of shot regions on the substrate indicates a shot region as the target of the imprint process to be performed.

FIGS. 2B to 2E are views illustrating the detailed configuration of the substrate holding unit 2. FIG. 2B is a view illustrating the substrate holding unit 2 viewed from the upper surface (the holding surface that holds the substrate 1). As shown in FIG. 2B, (the holding surface of) the substrate holding unit 2 includes a plurality of holding regions 22a, 22b, and 22c defined by partitions 21a, 21b, and 21c. In FIG. 2B, the plurality of holding regions 22a, 22b, and 22c are regions defined in a concentric structure, that is, concentrically.

FIGS. 2C to 2E are sectional views of the substrate holding unit 2 shown in FIG. 2B taken along a line A—A, and show only a portion corresponding to the shot region 11 on the substrate. The plurality of holding regions 22a, 22b, and 22c of the substrate holding unit 2 are connected to a pressure adjustment unit 26 via tubes 23a, 23b, and 23c, respectively. The pressure adjustment unit 26 has a function of adjusting pressures in spaces SPa, SPb, and SPc between the plurality of holding regions 22a, 22b, and 22c and (the shot region 11 of) the substrate 1. In other words, the pressure adjustment unit 26 has a function of adjusting the pressure to be applied to the lower surface of the substrate 1 in each of the plurality of holding regions 22a, 22b, and 22c. In this embodiment, the pressures in the spaces SPa, SPb, and SPc between the substrate 1 and the plurality of holding regions 22a, 22b, and 22c are independently controlled via the pressure adjustment unit 26 under the control of the control unit 14.

For example, FIG. 2C shows a state in which the pressures in the spaces SPa, SPb, and SPc between the substrate 1 and the plurality of holding regions 22a, 22b, and 22c are controlled such that the substrate 1 becomes flat. FIG. 2D shows a state in which from the state shown in FIG. 2C, the pressure in the space SPa between the holding region 22a and the substrate 1 is changed to the positive pressure side to deform (an end of) the substrate 1 upward. FIG. 2E shows a state in which from the state shown in FIG. 2C, the pressure in the space SPa between the holding region 22a and the substrate 1 is changed to the negative pressure side to deform (an end of) the substrate 1 downward.

When the pressures in the spaces SPa, SPb, and SPc between the substrate 1 and the plurality of holding regions 22a, 22b, and 22c of the substrate holding unit 2 are thus controlled, the shape of the substrate 1 can be changed relatively freely. In this embodiment, the overlay accuracy between (the pattern 3a of) the mold 3 and (the shot region 11 of) the substrate 1 is improved using this function. Note that the overlay accuracy between the mold 3 and the substrate 1 can be measured using, for example, the alignment measurement system 10, or can be measured using an overlay inspection apparatus that is an apparatus outside the imprint apparatus 100.

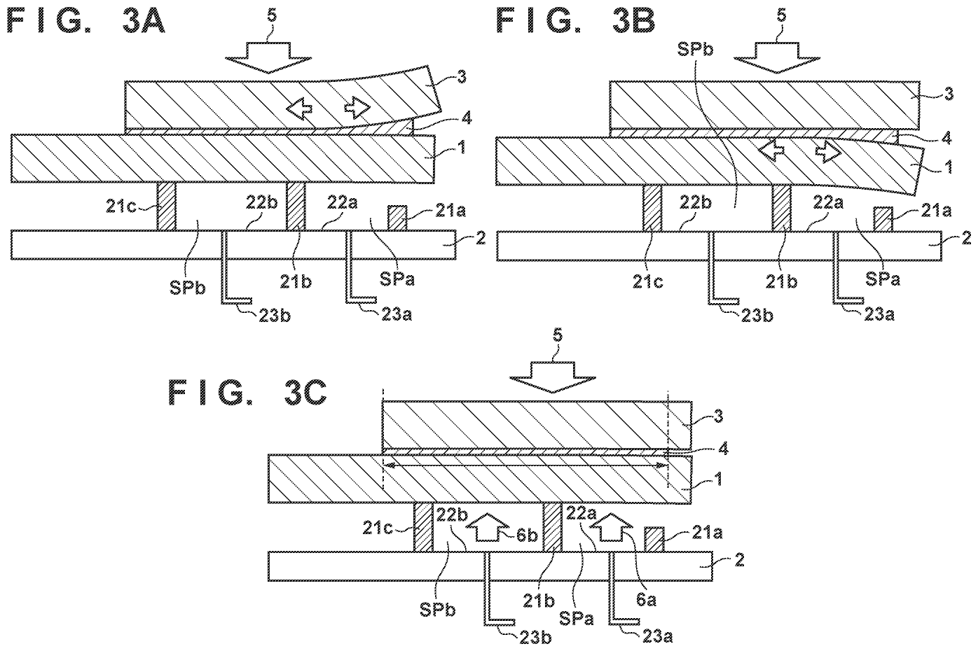

FIGS. 3A to 3C are views schematically illustrating the shapes (deformations) of the mold 3 and the substrate 1 in the imprint process, more specifically, in the contact step and the filling step. In the contact step and the filling step, the substrate 1 is deformed in accordance with a pressing force 5 applied to the mold 3 or pressures 6a and 6b in the spaces SPa and SPb between the substrate 1 and the holding regions 22a and 22b. As described above, the pattern 3a to be transferred to the substrate 1 is formed on the surface of the mold 3, which is in contact with the imprint material 4 on the substrate.

FIG. 3A shows a state in which the pressing force 5 applied to the mold 3 is small. Referring to FIG. 3A, since the mold 3 is deformed upward (in a concave shape) due to the pressing force 5 applied to the mold 3, (the pattern 3a of) the mold 3 is deformed to be extended relative to the substrate 1.

FIG. 3B shows a state in which the pressing force 5 applied to the mold 3 is large. Referring to FIG. 3B, since the pressing force 5 applied to the mold 3 is large, the mold 3 becomes flat. On the other hand, the substrate 1 is deformed downward (in a convex shape), and the upper surface of the substrate 1 is thus deformed to be extended relatively. Note that if, of the partitions 21a to 21c defining the plurality of holding regions 22a to 22c of the substrate holding unit 2, the partition 21a at the outermost periphery (on the outermost side) has a height lower than those of the remaining partitions 21b and 21c, as in this embodiment, the downward deformation of the substrate 1 is conspicuous.

FIG. 3C shows a state in which the pressing force 5 is applied to the mold 3, and at the same time, the pressures 6a and 6b in the spaces SPa and SPb between the substrate 1 and the holding regions 22a and 22b are controlled (raised). Referring to FIG. 3C, when the pressing force 5 applied to the mold 3 and the pressures 6a and 6b in the spaces SPa and SPb are balanced, the mold 3 and the substrate 1 can be made flat. More specifically, the pressure 6a in the space SPa can be obtained by equation (1) below in accordance with a contact area 211 between the mold 3 and the imprint material 4 on the substrate in the shot region 11 on the substrate. The pressure 6b in the space SPb can also be obtained like the pressure 6a. In equation (1), PP is the pressing force 5, and CA is the contact area 211.

pressure 6a(6b)=PP/CA (1)

Note that in this embodiment, the pressures in the spaces SPa to SPc between the substrate 1 and the plurality of holding regions 22a to 22c of the substrate holding unit 2 are controlled such that the substrate 1 becomes flat. However, the present invention is not limited to this. For example, the pressures in the spaces SPa to SPc between the substrate 1 and the plurality of holding regions 22a to 22c of the substrate holding unit 2 may be controlled such that deformation that occurs in the substrate 1 due to the pressing force 5 falls within an allowable range (such that the substrate 1 obtains a target shape).

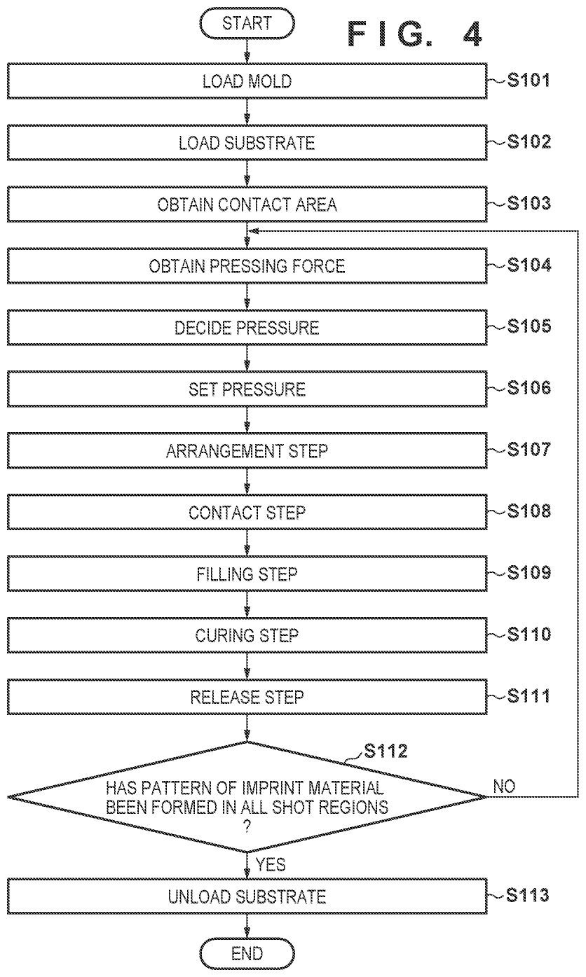

An example of the operation (imprint method) of the imprint apparatus 100 will be described with reference to FIG. 4. This operation is performed by the control unit 14 comprehensively controlling the units of the imprint apparatus 100, as described above.

In step S101, the mold 3 is loaded into the imprint apparatus 100. More specifically, the mold 3 is loaded into the imprint apparatus 100 by a mold conveyance unit (not shown), and the mold 3 is then held by the mold stage 50 (mold holding unit 51).

In step S102, the substrate 1 is loaded into the imprint apparatus 100. More specifically, the substrate 1 is loaded into the imprint apparatus 100 by a substrate conveyance unit (not shown), and the substrate 1 is then held by the substrate stage 60 (substrate holding unit 2) via the prealignment unit 7.

In step S103, the contact area between the mold 3 and the imprint material on the substrate in the shot region 11 on the substrate (the contact area 211 in a state in which the whole surface of the pattern surface of the mold 3 and the imprint material 4 on the substrate are totally brought into contact with each other, as shown in FIG. 3C) is obtained. More specifically, the control unit 14 obtains a shot layout from information about the imprint process input via the console unit 15, that is, an imprint recipe. Then, the control unit 14 extracts the area of each shot region on the substrate from the shot layout and obtains the area as the contact area between the mold 3 and the imprint material on the substrate. Note that a case where the imprint material is not arranged on the whole surface of the shot region 11 on the substrate, for example, a case where the imprint material is not arranged in a region (margin region) having a predetermined width from the outer periphery of the shot region 11 can also be considered. In this case, the control unit 14 obtains a drop pattern from the imprint recipe and obtains the contact area between the mold 3 and the imprint material on the substrate in consideration of the drop pattern in addition to the shot layout. Thus, the control unit 14 obtains information (second information) about the contact area between the mold and the imprint material when the mold and the imprint material on the substrate are brought into contact with each other (functions as a second obtaining unit).

In step S104, the pressing force applied to the mold 3 when the mold 3 and the imprint material on the substrate are brought into contact with each other is obtained. More specifically, the control unit 14 obtains a shot layout from information about the imprint process input via the console unit 15, that is, an imprint recipe. Then, the control unit 14 extracts, from the shot layout, the force applied to the mold 3 when the mold 3 and the imprint material on the substrate are brought into contact with each other, and obtains the force as the pressing force. Thus, the control unit 14 obtains information (first information) about the pressing force applied to the mold 3 when the mold 3 and the imprint material on the substrate are brought into contact with each other (functions as a first obtaining unit). Note that if a load cell is provided on the mold stage 50, a measured value (actually measured value) obtained by the load cell when the mold 3 and the imprint material on the substrate are brought into contact with each other may be obtained as the pressing force.

In step S105, based on the contact area obtained in step S103 and the pressing force obtained in step S104, the pressures in the spaces SPa to SPc between the substrate and the plurality of holding regions 22a to 22c of the substrate holding unit 2 are decided. More specifically, the control unit 14 decides the pressures in the spaces SPa to SPc in accordance with a value obtained by substituting the contact area obtained in step S103 and the pressing force obtained in step S104 to equation (1) described above.

In step S106, the pressures in the spaces SPa to SPc between the substrate 1 and the plurality of holding regions 22a to 22c of the substrate holding unit 2 are set in accordance with the pressures decided in step S105. More specifically, the control unit 14 controls, via the pressure adjustment unit 26, the pressures in the spaces SPa to SPc between the substrate 1 and the plurality of holding regions 22a to 22c of the substrate holding unit 2 to the pressures decided in step S105.

In step S107, the arrangement step of arranging (supplying) the imprint material on the substrate is performed. More specifically, the control unit 14 arranges the imprint material in the shot region 11 on the substrate via the dispenser 8.

In step S108, the contact step of bringing the mold 3 and the imprint material on the substrate into contact with each other is performed. More specifically, the control unit 14 brings the mold 3 and the imprint material on the substrate into contact with each other in a state in which the pattern 3a of the mold 3 is deformed in a convex shape to the substrate side via the pressure adjustment device connected to the space 12 defined by the light transmitting member 13 and the cavity 3b. Then, the pressure applied from the pressure adjustment mechanism to the space 12 is gradually decreased, thereby bringing the whole surface of the mold 3 into contact with the imprint material on the substrate.

In step S109, in a state in which the imprint material on the substrate and the mold 3 are in contact with each other, the filling step of filling the pattern 3a of the mold 3 with the imprint material is performed. More specifically, the control unit 14 maintains the state in which the whole surface of the mold 3 is in contact with the imprint material on the substrate until the pattern 3a of the mold 3 is filled with the imprint material. At this time, overlay (alignment) between the mold 3 and the substrate 1 is preferably adjusted based on the measurement result of the alignment measurement system 10.

In step S110, in the state in which the imprint material on the substrate and the mold 3 are in contact with each other, the curing step of curing the imprint material is performed. More specifically, in the state in which the imprint material on the substrate and the mold 3 are in contact with each other, the control unit 14 irradiates the imprint material with light from the irradiation unit 16, thereby curing the imprint material on the substrate.

In step S111, the release step of releasing the mold 3 from the cured imprint material on the substrate is performed. The pattern of the cured imprint material is thus formed on the substrate.

In step S112, it is determined whether the pattern of the imprint material is formed in all shot regions on the substrate. If the pattern of the imprint material is not formed in all shot regions on the substrate, the process returns to step S104 to form the pattern of the imprint material in the next shot region, and steps S104 to S112 are repeated. On the other hand, if the pattern of the imprint material is formed in all shot regions on the substrate, the process advances to step S113.

In step S113, the substrate 1 is unloaded from the imprint apparatus 100. More specifically, the substrate 1 on which the pattern of the imprint material is formed in each shot region is unloaded from the substrate stage 60 to the outside of the imprint apparatus 100 by a substrate conveyance unit (not shown).

As described above, in this embodiment, the pressures in the spaces SPa to SPc between the substrate 1 and the plurality of holding regions 22a to 22c of the substrate holding unit 2 are controlled based on the pressing force applied to the mold 3 when the mold 3 and the imprint material on the substrate are brought into contact with each other. Thus, in the imprint process, more specifically, in the contact step and the filling step, deformation that occurs in the substrate 1 due to the pressing force can be made to fall within an allowable range, and for example, the substrate 1 can be made flat. Hence, according to this embodiment, it is possible to maintain and improve the overlay accuracy between (the pattern 3a of) the mold 3 and (the shot region of) the substrate 1. Such control is particularly useful in a peripheral shot region in which the height of the partition 21a at the outermost periphery is lower than those of the remaining partitions 21b and 21c, and downward deformation that occurs in the substrate 1 due to the pressing force applied to the mold 3 is conspicuous.

Also, when the pressing force applied to the mold 3 in the contact step and the filling step is obtained as time-series data, for example, even if the pressing force is changed when adjusting overlay between the mold 3 and the substrate 1, the overlay accuracy can be maintained and improved. Note that if the pressing force is changed when adjusting overlay between the mold 3 and the substrate 1, as described above, the measured value obtained by the load cell provided on the mold stage 50 may be obtained in real time as the pressing force.

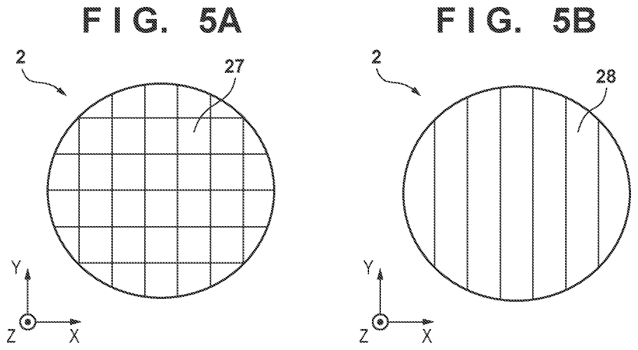

Also, in this embodiment, as shown in FIG. 2B, the plurality of holding regions 22a, 22b, and 22c of the substrate holding unit 2 are concentrically defined regions. However, the present invention is not limited to this. For example, the plurality of holding regions of the substrate holding unit 2 may be rectangularly defined regions, as shown in FIGS. 5A and 5B. FIGS. 5A and 5B are views illustrating the substrate holding unit 2 viewed from the upper surface (the holding surface that holds the substrate 1).

In FIG. 5A, a plurality of holding regions 27 of the substrate holding unit 2 are defined in a grid shape. Each of the plurality of holding regions 27 may be, for example, a region having the same shape and size as one shot region on the substrate. Also, each of the plurality of holding regions 27 may be a region smaller than one shot region on the substrate. Hence, when the pressures in the spaces between the substrate 1 and the plurality of holding regions 27 of the substrate holding unit 2 are controlled, the shape of the substrate 1 can be changed more freely. It is therefore possible to provide more excellent accuracy in overlay between the mold 3 and the substrate 1. Note that if each of the plurality of holding regions 27 is a region having the same shape and size as one shot region on the substrate, the pressure can simply be set (decided) from the pressing force and the contact area. Hence, control of the pressures in the spaces between the substrate 1 and the plurality of holding regions 27 of the substrate holding unit 2 can be made simpler.

In FIG. 5B, a plurality of holding regions 28 of the substrate holding unit 2 are defined in strips. The structure of the substrate holding unit 2 (holding regions 28) shown in FIG. 5B is formed by more simplifying the structure of the substrate holding unit 2 (holding regions 27) shown in FIG. 5A. When the structure of the substrate holding unit 2 is thus simplified, the cost of the substrate holding unit 2 can be reduced, and control of the pressures in the spaces between the substrate 1 and the plurality of holding regions 28 of the substrate holding unit 2 can be made simpler. This contributes to improvement of response of pressure control.

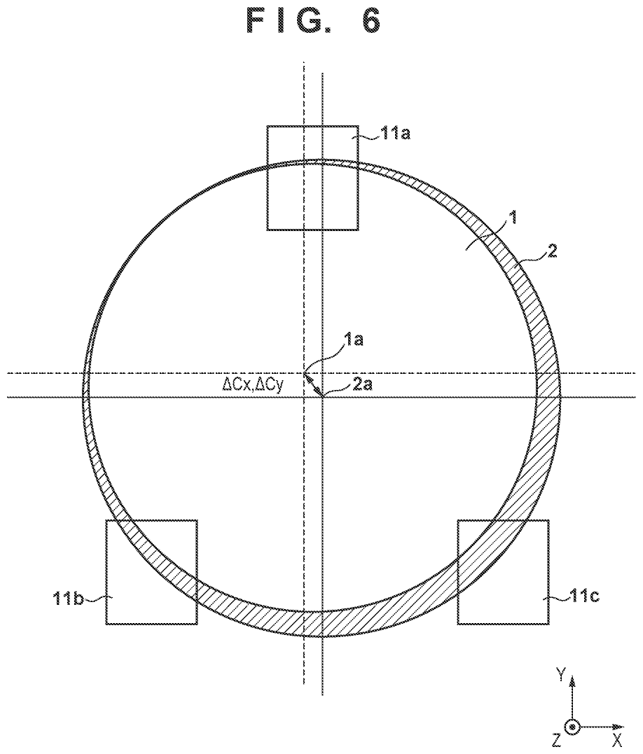

Also, in the imprint apparatus 100, as shown in FIG. 6, when the substrate holding unit 2 holds the substrate 1, a position deviation of the substrate 1 may occur with respect to the substrate holding unit 2. For example, in FIG. 6, since a center position 1a of the substrate 1 deviates from a center position 2a of the substrate holding unit 2, a position deviation (ΔCx, ΔCy) of the substrate 1 occurs. The position deviation of the substrate 1 with respect to the substrate holding unit 2 causes, for example, a change in the contact area (the area of each shot region) between the mold 3 and the imprint material on the substrate in each of shot regions 11a, 11b, and 11c on the substrate. As a result, errors occur in the pressures in the spaces between the substrate 1 and the plurality of holding regions of the substrate holding unit 2, which are obtained from the pressing force applied to the mold 3, and the overlay accuracy between the mold 3 and the substrate 1 lowers.

If the position deviation of the substrate 1 occurs with respect to the substrate holding unit 2, in this embodiment, the off-axis alignment measurement system 9 measures the position of an alignment mark provided on the substrate 1 and the position of the outer edge of the substrate 1. The control unit 14 can obtain the position deviation (ΔCx, ΔCy) of the substrate 1 based on the measurement result of the off-axis alignment measurement system 9. Thus, the off-axis alignment measurement system 9 and the control unit 14 obtain information (third information) about the position deviation of the substrate 1 held by the substrate holding unit 2 with respect to the substrate holding unit 2 (function as a third obtaining unit). If the position deviation (ΔCx, ΔCy) of the substrate 1 with respect to the substrate holding unit 2 is obtained, the contact area between the mold 3 and the imprint material on the substrate can be obtained (recalculated) based on the position deviation (ΔCx, ΔCy). The thus obtained contact area is substituted into equation (1) described above, thereby deciding the pressures in the spaces between the substrate 1 and the plurality of holding regions of the substrate holding unit 2 without generating an error due to the position deviation of the substrate 1. Hence, even if the position deviation of the substrate 1 occurs with respect to the substrate holding unit 2, lowering of the overlay accuracy between the mold 3 and the substrate 1 can be suppressed (prevented). Note that the measuring device that measures the position of the outer edge of the substrate 1 is not limited to the off-axis alignment measurement system 9, and a length measuring sensor that measures the height of the substrate 1 may be used.

The pattern of a cured product formed using the imprint apparatus 100 is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

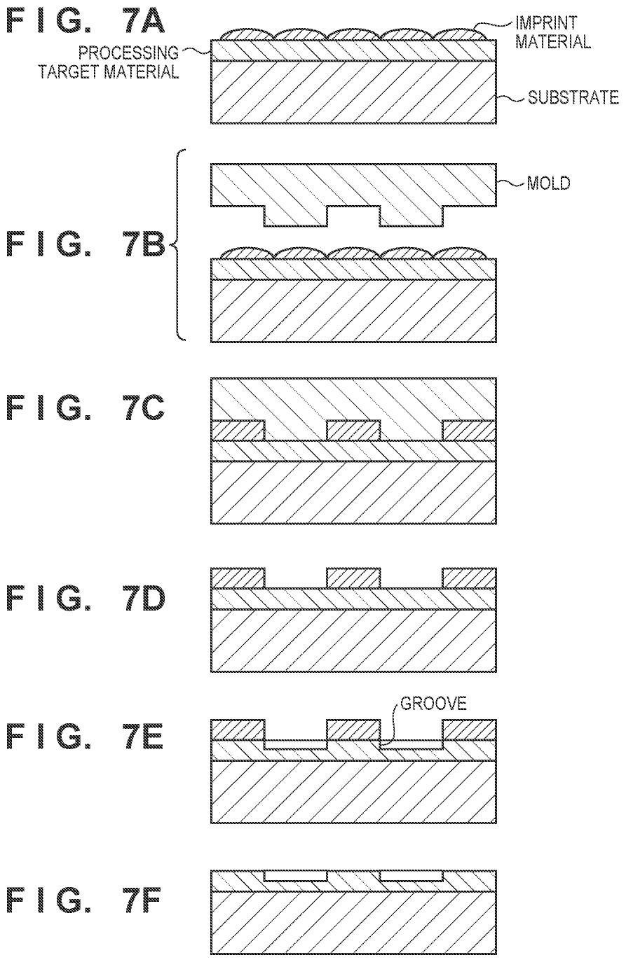

Next, description regarding a detailed method of manufacturing an article is given. As illustrated in FIG. 7A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 7B, a side of the mold for imprint with a projection and groove pattern is formed on and caused to face the imprint material on the substrate. As illustrated in FIG. 7C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 7D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 7E, when etching is performed using the pattern of the cured product as an etching resistant mask, a portion of the surface of the processed material where the cured product does not exist or remains thin is removed to form a groove. As shown in FIG. 7F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2022-093817 filed on Jun. 9, 2022, which is hereby incorporated by reference herein in its entirety.

What is claimed is:

1. An imprint apparatus that forms a pattern of an imprint material on a substrate using a mold, comprising:
a substrate holding unit including a plurality of holding regions whose pressures to the substrate are independently controlled, and configured to hold the substrate on the plurality of holding regions;
a first obtaining unit configured to obtain first information about a pressing force applied to the mold when the mold and the imprint material on the substrate are brought into contact with each other; and
a control unit configured to control, based on the first information obtained by the first obtaining unit, the pressure between the substrate and each of the plurality of holding regions in a state in which the mold and the imprint material on the substrate are in contact with each other such that deformation that occurs in the substrate due to the pressing force falls within an allowable range.

2. The apparatus according to claim 1, wherein the control unit controls the pressure between the substrate and each of the plurality of holding regions such that the substrate becomes flat in a state in which the mold and the imprint material on the substrate are in contact with each other, and the pressing force is applied to the mold.

3. The apparatus according to claim 1, wherein the control unit controls the pressure between the substrate and each of the plurality of holding regions such that in each of the plurality of holding regions, the pressure between the holding region and the substrate balances the pressing force.

4. The apparatus according to claim 1, further comprising a second obtaining unit configured to obtain second information about a contact area between the mold and the substrate in a state in which a whole surface of a pattern surface of the mold and the imprint material on the substrate are in contact with each other,
wherein the control unit controls, based on the second information obtained by the second obtaining unit as well, the pressure between the substrate and each of the plurality of holding regions such that the deformation that occurs in the substrate due to the pressing force falls within the allowable range.

5. The apparatus according to claim 4, wherein in each of the plurality of holding regions, the control unit controls the pressure between the holding region and the substrate to PP/CA.

6. The apparatus according to claim 4, further comprising a third obtaining unit configured to obtain third information about a position deviation of the substrate held by the substrate holding unit with respect to the substrate holding unit,
wherein the control unit controls, based on the third information obtained by the third obtaining unit as well, the pressure between the substrate and each of the plurality of holding regions such that the deformation that occurs in the substrate due to the pressing force falls within the allowable range.

7. The apparatus according to claim 6, further comprising a measurement system configured to measure a position of a mark provided on the substrate and a position of an outer edge of the substrate,
wherein the position deviation is obtained from the position of the mark and the position of the outer edge, which are measured by the measurement system.

8. The apparatus according to claim 1, wherein the plurality of holding regions are concentrically defined regions.

9. The apparatus according to claim 1, wherein the plurality of holding regions are rectangularly defined regions.

10. The apparatus according to claim 1, wherein each of the plurality of holding regions is a region smaller than one shot region on the substrate.

11. The apparatus according to claim 1, further comprising a plurality of partitions provided in the substrate holding unit to define the plurality of holding regions,
wherein of the plurality of partitions, a partition on an outermost side has a height lower than those of the remaining partitions.

12. An imprint method for forming a pattern of an imprint material on a substrate using a mold, comprising:
holding the substrate by a substrate holding unit including a plurality of holding regions whose pressures to the substrate are independently controlled;
obtaining information about a pressing force applied to the mold when the mold and the imprint material on the substrate are brought into contact with each other; and
controlling, based on the information, the pressure between the substrate and each of the plurality of holding regions in a state in which the mold and the imprint material on the substrate are in contact with each other such that deformation that occurs in the substrate due to the pressing force falls within an allowable range.

13. An article manufacturing method comprising:
forming a pattern on a substrate using an imprint method defined in claim 12;
processing the substrate on which the pattern is formed in the forming; and
manufacturing an article from the processed substrate.
